(19) United States
(12) Patent Application Publication
(10) Pub. No.: US 2002/0106880 A1
(43) Pub. Date: Aug. 8, 2002

(54) Method for avoiding the junction leakage

(76) Inventors: Po-Chao Tsao, Taipei (TW); Der-Yuan Wu, Hsin-Chu City (TW); Chih-Yuan Hsiao, Feng-Shan City (TW)

Correspondence Address: Powell, Goldstein, Frazer & Murphy, LLP, Suite 600, 1001 Pennsylvanic Avenue, Washington, DC, 20004, US

(21) Appl. No.: 09/776,744

(22) Filed: Feb. 5, 2001

(51) Int. Cl. H01L 21/04; H01L 21/3205; H01L 21/4763

(52) U.S. Cl. 438/592; 438/510; 438/586; 438/595

(57) ABSTRACT

First of all, a junction protecting layer are formed on the semiconductor substrate. The junction protecting layer is then etched to expose a partial surface of the semiconductor substrate as an opening. Next, a semiconductor layer is formed over the junction protecting layer to fill the opening. After forming a gate on the semiconductor layer, implanting the LDD in the semiconductor layer. Afterward, a spacer layer is conformed along the surfaces of the gate and the LDD. Subsequently, performing an etching process to etch through the spacer layer, the semiconductor layer, and the junction protecting layer until exposing the partial surfaces of the semiconductor substrate, so as to form the etched regions and a spacer beside each sidewall of the gate. Finally, the source/drain region is formed respectively in each etched region, after the etched regions are filled with the material the same with the substrate.

### BACKGROUND OF THE INVENTION

1. Field of the Invention

The present invention relates generally to a method for forming a metal-oxide-semiconductor device, and more particularly to a method for forming a metal-oxide-semiconductor device with junction protecting layer.

2. Description of the Prior Art

As semiconductor devices, such as Metal-Oxide-Semiconductor (MOS) devices, become highly integrated, the area occupied of the chip has to be maintained or more less, so as to reduce the unit cost of the circuit. For corresponding with the development of the high technology industry in the future, there is only one method to achieve this objective, that is, the area occupied by the devices shrinks, as well as the design rule. With advances in the semiconductor technology, the dimensions of the integrated circuit (IC) devices have been shrunk to the deep sub-micron range. As the semiconductor device continuously shrinks to deep sub-micron region, some problems are incurred due to the process of scaling down.

A cross-sectional view of a Metal-Oxide-semiconductor device of the know prior art is illustrated in FIG. 1. First of all, a semiconductor substrate 100, such as a silicon substrate, is provided. The semiconductor substrate 100 includes shallow trench isolation 110, and which collocates to form a gate oxide layer 120 and a gate 130 on the surface of the semiconductor substrate 100. Lightly doping drain regions 140 is formed in the semiconductor substrate 100 after an ion implantation is performed. Afterward, an oxide spacer 150 are formed on the sidewall of the gate 130. Next, a heavily doping of ion implantation is performed to form a source/drain regions 160 in the substrate 100 wherein the source/drain regions 160 are separate at a predetermined distance as a channel 170 from each other. Obviously, in the conventional process for forming a metal-oxide-semiconductor device, the gate width corresponds with effective channel length thereof, and, hence, it is fixed.

Moreover, if a semiconductor device with high speed is necessary, a semiconductor device with small size has to be fabricated. For this reason, the effective channel length of the gate must be reduced. But the length of the Metal-Oxide-Semiconductor device can not be unlimitedly reduced, because the variable derivational problem will be produced due to the channel length is reduced. Accordingly, this phenomenon is called “Short Channel Effect”. When the size of the device is reduced, the junction on the source/drain regions must be shallow to match up with, so as to avoid the short channel effect. Furthermore, the overlapped channel that is formed by way of the source/drain extension at high temperature can not be reduced due to the size of the gate is fixed by using the conventional process. On the other hand, ions can not be implanted deep into the substrate during forming the source/drain region. Therefore, the junction leakage is not reduced.

To avoid the short channel effect, another method for forming the metal-oxide-semiconductor device is provided in the conventional process, as shown in FIG. 2, which reference is now made. First of all, a semiconductor substrate 200, such as a silicon substrate, is provided. The semiconductor substrate 200 includes shallow trench isolation 210, and which collocates to form a gate oxide layer 220 and a gate 230 on the surface of the semiconductor substrate 200. Lightly doping drain regions 240 is formed in the semiconductor substrate 200 after an ion implantation is performed. Afterward, an oxide spacer 250 are formed on the sidewall of the gate 230. Next, a heavily doping of ion implantation is performed to form a source/drain regions 260 in the substrate 200, wherein the source/drain regions 260 are separate at a predetermined distance as a channel 270 from each other. Subsequently, a pocket ion implantation is performed to form the pocket dopant regions 280 at the channel 270 close to sides of the source/drain regions 260.

As about discussed, increasing the dopant's concentration of the pocket implantation for decreasing the short channel effect is necessary. In general, to optimize the punchthrough of the implanted region, such as Boron, can be implanted into the junctions, and the threshold implant dosage is quite high. Using the Boron as pocket dopant will rapidly increase pocket distribution and electron distribution along the channel. If the pocket dopant is overdose, it will tend to spread out in the channel and result in issues of the side effect, such as junction capatance is increased due to increase the junction leakage and the performance is worse. Therefore, the yield and quality of the process are decreased and, hence, increased cost.

In accordance with the above description, a new and improved method for forming the metal-oxide-semiconductor is therefore necessary, so as to raise the yield and quality of the follow-up process.

### SUMMARY OF THE INVENTION

In accordance with the present invention, a method is provided for fabricating the metal-oxide-semiconductor that substantially overcomes drawbacks of above mentioned problems arised from the conventional methods.

Accordingly, it is a main object of the present invention to provide a method for fabricating the metal-oxide-semiconductor devices. This invention can avoid causing junction leakage by forming the junction protecting layer, so as to substitute for pocket dopant region and avoid defect of pocket dopant, which is easy to diffuse. Hence, the present invention is appropriate for deep sub-micron technology to provide the semiconductor devices.

Another object of the present invention is to provide a method for forming the metal-oxide-semiconductor devices with the junction protecting layer. The present invention can form a source/drain region deep than conventional process by means of the junction protecting layer. Furthermore, the junction protecting layer not only could reduce side effects of above, but also eliminate short channel effect. Accordingly, this invention can provide a metal-oxide-semiconductor device whose performance is better than the conventional one, so as to increase yield and quality of the process and, hence, decrease cost. Therefore, the present invention can correspond to economic effect.

In accordance with the present invention, a new method for forming semiconductor devices is disclosed. First of all, a semiconductor substrate is provided. Then a junction protecting layer are formed on the semiconductor substrate. Next, a photoresister layer is formed and defined on the junction protecting layer. The junction protecting layer is then etched by the photoresister layer as a mask to expose a partial surface of the semiconductor substrate as an opening. After removing the photoresister layer, a semiconductor layer is formed over the junction protecting layer to fill the opening. Subsequently, forming a gate oxide layer on the semiconductor layer, and then forming a gate on the gate oxide layer by means of the conventional process. Next, the lightly doped drain regions (LDD) are formed in the semiconductor layer by conventional implanted process, wherein the thickness of the lightly doped drain regions is about equal to the semiconductor layer. Afterward, a spacer layer is conformed along the surfaces of the gate and the gate oxide layer. Etching through the spacer layer, the gate oxide layer, the semiconductor layer, and the junction protecting layer until exposing the partial surfaces of the semiconductor substrate by way of using an dry etching process, so as to form the etched regions and a spacer beside each sidewall of the gate. The etched regions are then filled with the material the same with the substrate. Subsequently, the source/drain region is formed respectively in the etched region. Finally, performing the follow-up process of the metal-oxide-semiconductor process as conventional process, such as salicide.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 show cross-sectional views illustrative of the metal-oxide-semiconductor by way of using the conventional process;

FIG. 2 show cross-sectional views illustrative of the metal-oxide-semiconductor having pocket implanting regions by way of using the conventional process;

FIG. 3A to FIG. 3C show cross-sectional views illustrative of various stages for forming a ion-implanting region in accordance with the first embodiment of the present invention;

FIG. 4A to FIG. 4G show cross-sectional views illustrative of various stages for forming a metal-oxide-semiconductor device in accordance with the second embodiment of the present invention; and

FIG. 5A to FIG. 5F show cross-sectional views illustrative of various stages for forming a metal-oxide-semiconductor device having salicide in accordance with the third embodiment of the present invention.

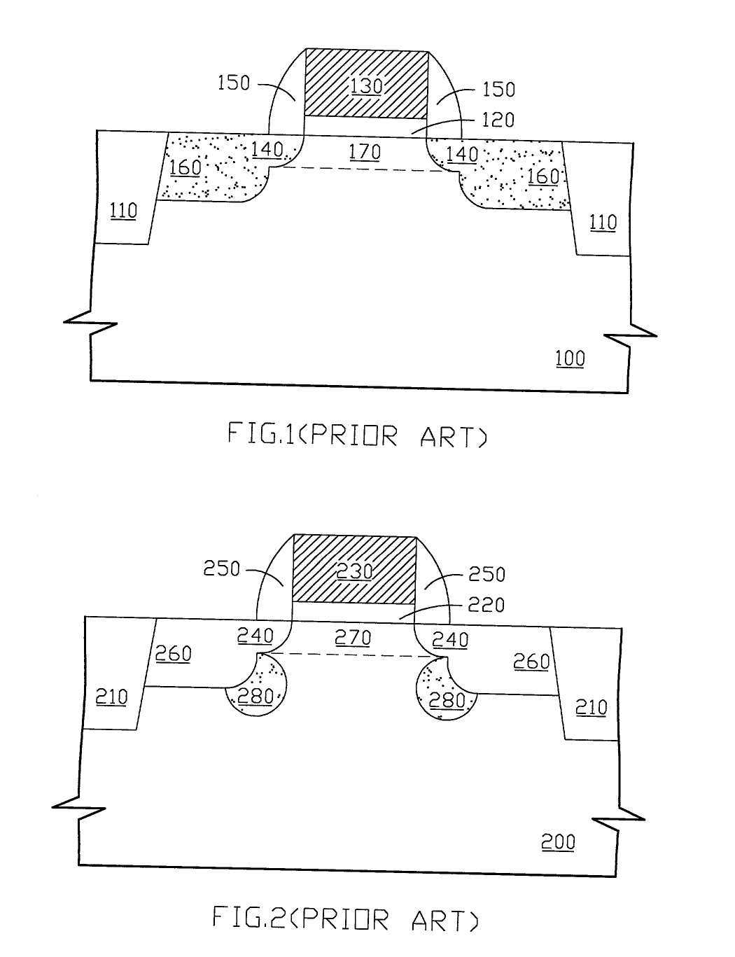

### DESCRIPTION OF THE PREFERRED EMBODIMENT

A preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

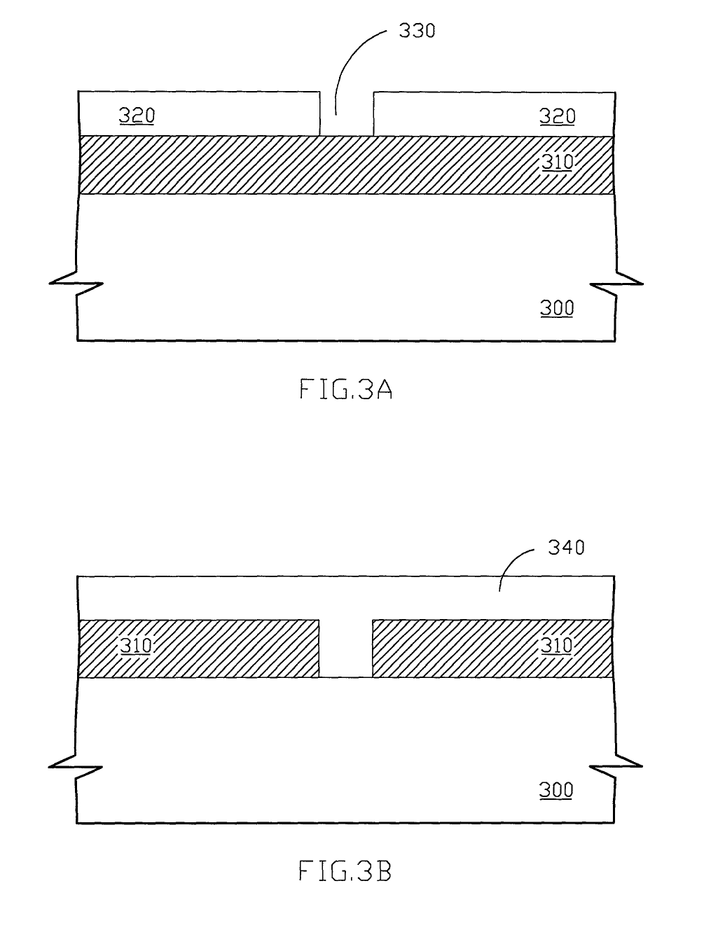

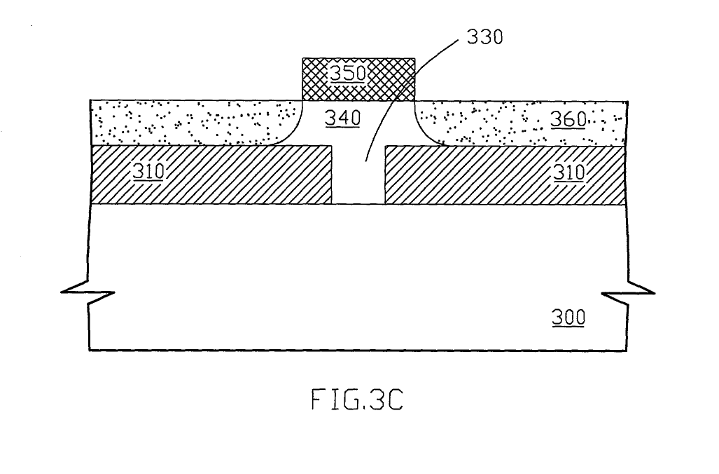

As illustrated in FIG. 3A, in the first embodiment of the present invention, first of all, a semiconductor substrate 300 is provided. Then a junction protecting layer 310 are formed on the semiconductor substrate 300. Next, a photoresister layer 320 is formed and defined on the junction protecting layer 310. The junction protecting layer 310 is then etched by the photoresister layer 320 as an etching mask to expose a partial surface of the semiconductor substrate 300 as an opening 330. After removing the photoresister layer 320, a semiconductor layer 340 is formed over the junction protecting layer 310 to fill the opening 330, as shown in FIG. 3B.

As illustrated in FIG. 3C, in this embodiment, forming an ion-mask 350 on the semiconductor layer 340, wherein the width of the opening 330 is less than the same one of the ion-mask 350. The ion-implanting regions 360 are then formed in the semiconductor layer 340 above the junction protecting layer 310 by conventional implanted process and the ion-mask 350, wherein the thickness of the ion-implanting regions 360 is about equal to the semiconductor layer 340 (or less than it). Finally, removing the ion-mask 350.

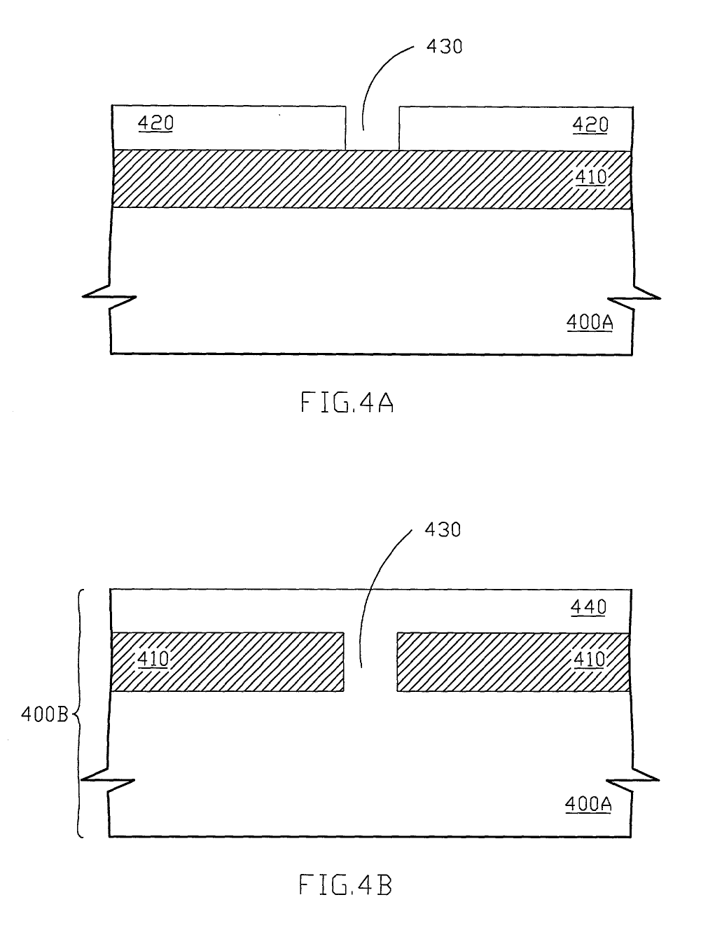

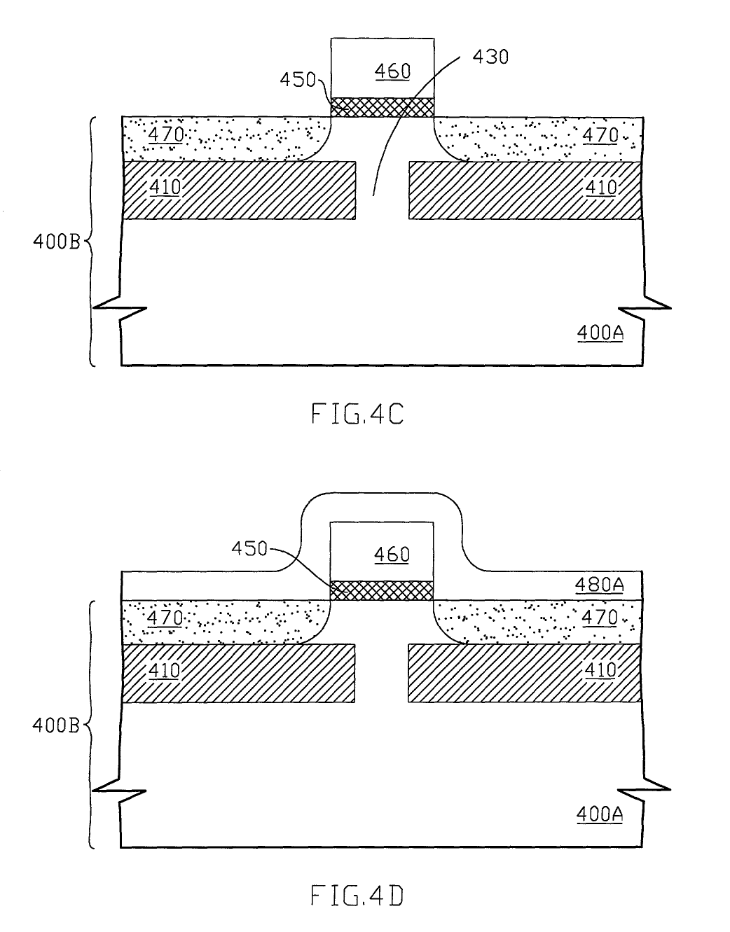

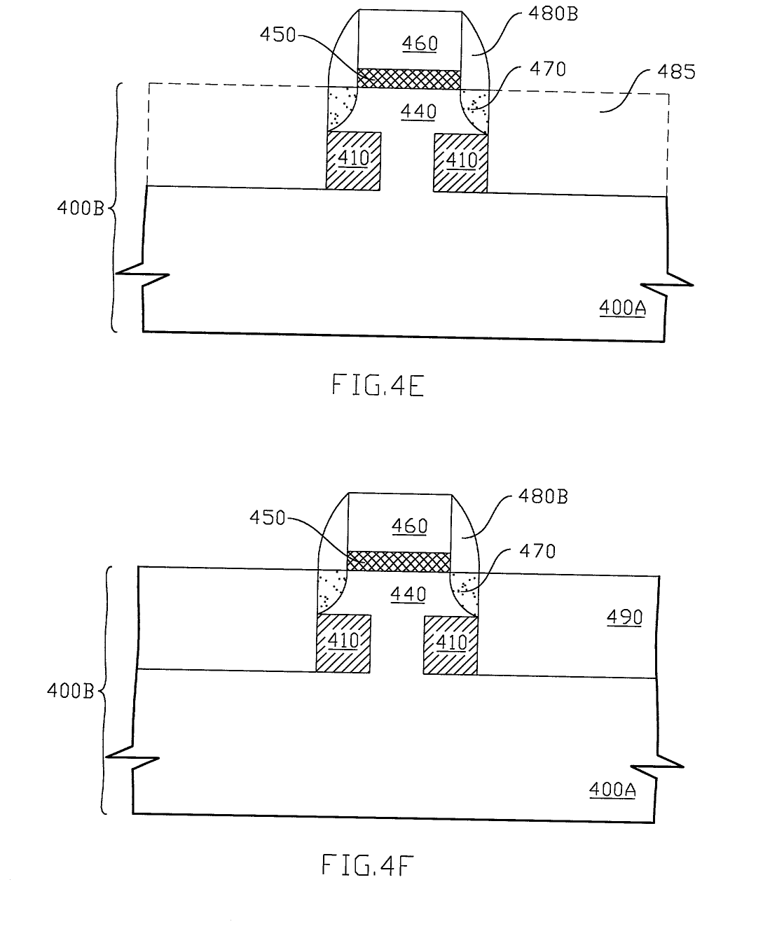

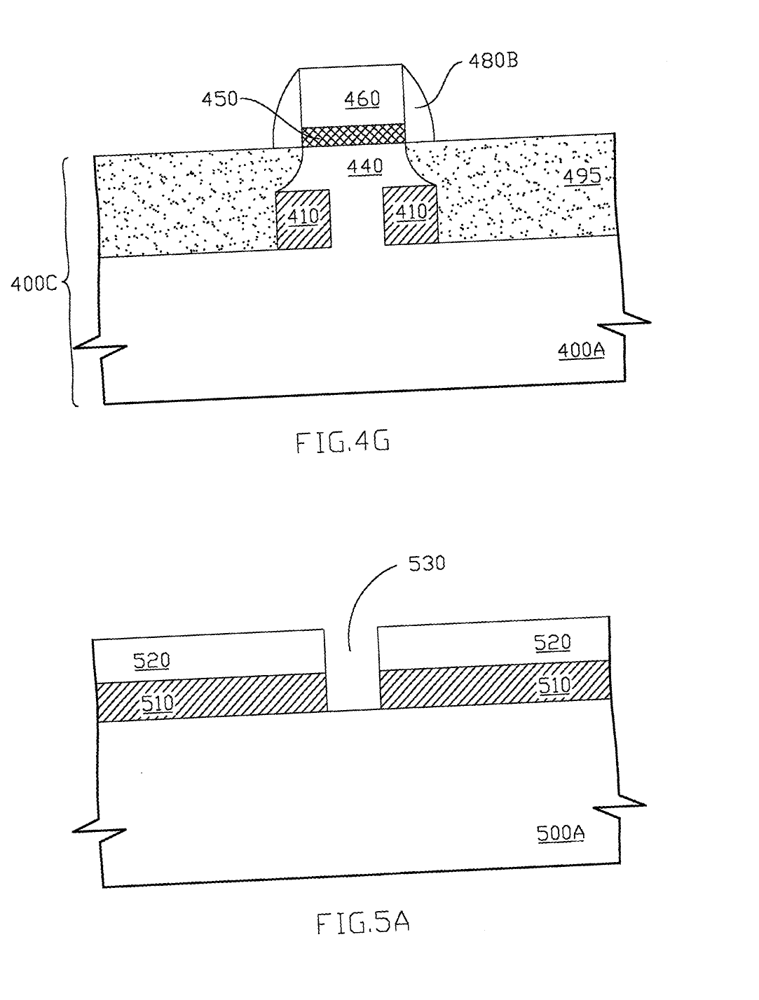

As illustrated in FIG. 4A, in the second embodiment of the present invention, first of all, a first substrate 400A, such as a silicon substrate, is provided. Then depositing a protecting layer 410 and forming on the first substrate 400A, wherein the thickness of the protecting layer 410 is about 500 Å to 800 Å. Next, a photoresister layer 420 is formed and defined on the protecting layer 410. The protecting layer 410 is then etched by the photoresister layer 420 as an etching mask to expose a partial surface of the first substrate 400A as an opening 430. After the photoresister layer 420 is removed, a thin layer 440, such as a silicon layer, is formed over the protecting layer 410 to fill the opening 430 by way of using the epitaxial process, wherein the thickness of the thin layer 440 is about 100 Å to 200 Å. A second substrate 400B combines the thin layer 440 with the first substrate 400A, as shown in FIG. 4B.

As illustrated in FIG. 4C, in this embodiment, forming a gate oxide layer 450 and a gate 460 on the second substrate 400B, wherein the width of the opening 430 is less than the same one of the gate 460. A first ion-implantion is then performed to form a first ion-implanting region 470, such as a lightly doped drain region (LDD), in the thin layer 440 of the second substrate 400B over the protecting layer 410, wherein the thickness of the first ion implanting region 460 is about equal to the thin layer 440 or less than it.

As illustrated in FIG. 4D, in this embodiment, a insulator layer 480A, such as a nitride layer, is conformed along the surfaces of the gate 460 and the gate oxide layer 450. The insulator layer 480A is etched by way of using an isotropic etching process, such as a dry etching process, to form a spacer 480B beside each sidewall of the gate 460. Proceeding to etch sequentially through the gate oxide layer 450, the thin layer 440, and the protecting layer 410 with the gate 460 having the spacer 480B as an etching mask until exposing the partial surfaces of the first substrate 400A, so as to form the etched regions 485 on the first substrate 400A, as shown in FIG. 4E.

As illustrated in FIG. 4F, in this embodiment, the etched regions 485 are filled with the material that is the same one of the first substrate 400A, such as a silicon material, to form the predetermined implanting regions 490, wherein the method for filling up the etched regions 485 comprises a selective epitaxy process to grow the above material on the first substrate 400A. A third substrate 400C combines the predetermined implanting regions 490 with the second substrate 400B, as shown in FIG. 4G. Subsequently, a second ion-implanting region 495, such as a source/drain region, is formed respectively in the predetermined implanting regions 490 by way of using the second ion-implanting process, wherein the thickness of the second ion-implanting region 495 is about equal to the same one of the predetermined implanting regions 490 or more than it, as shown in FIG. 4G. Finally, performing the follow-up process of the metal-oxide-semiconductor process as conventional process, such as salicide.

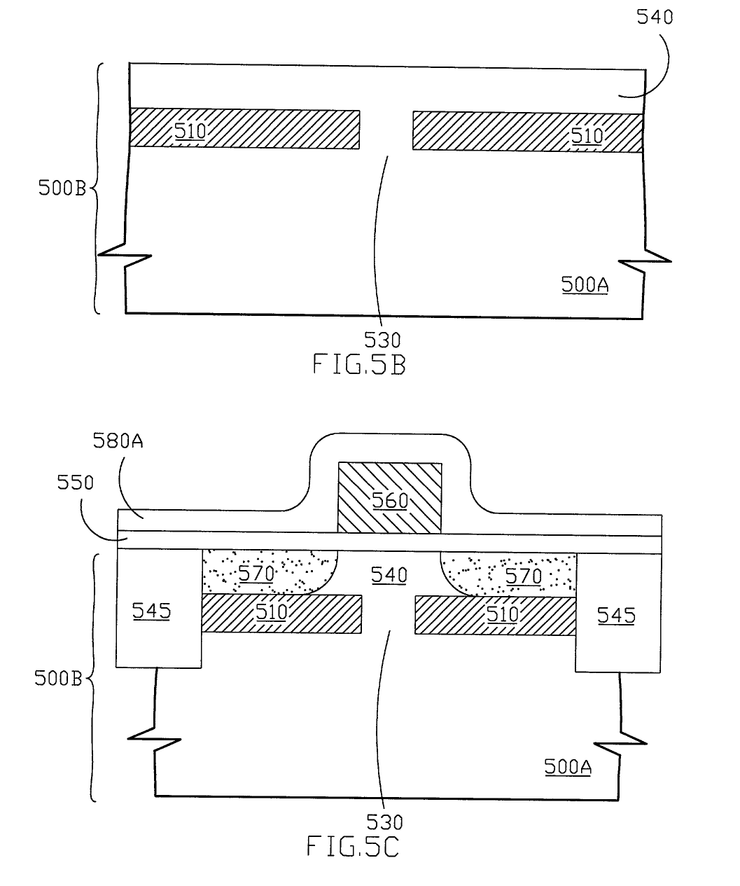

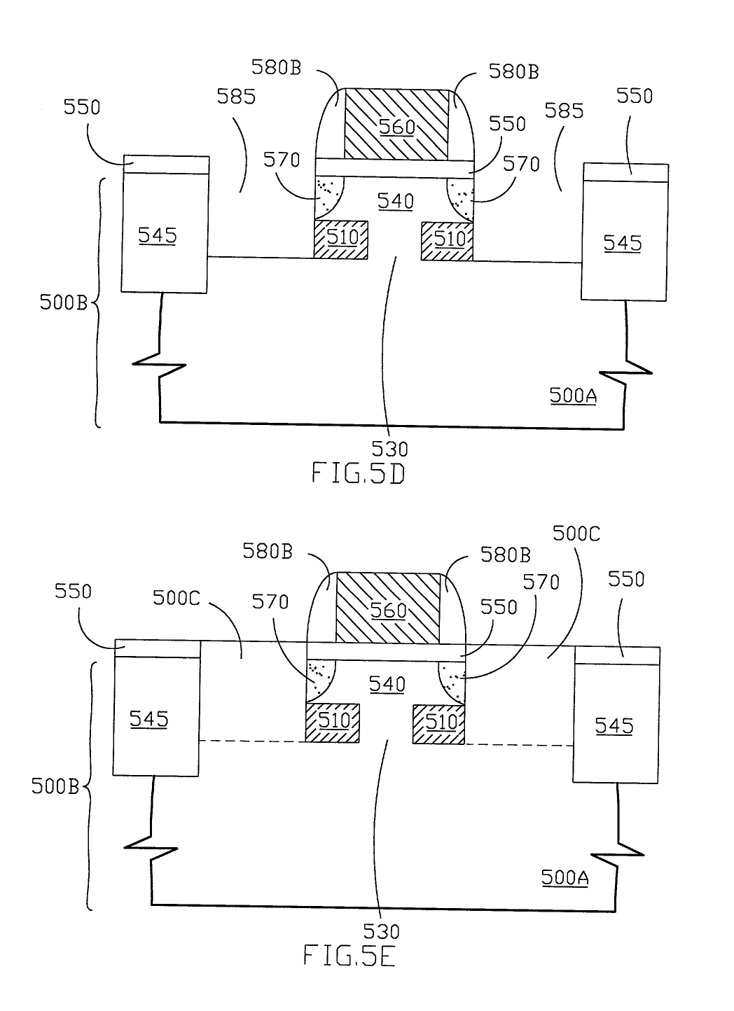

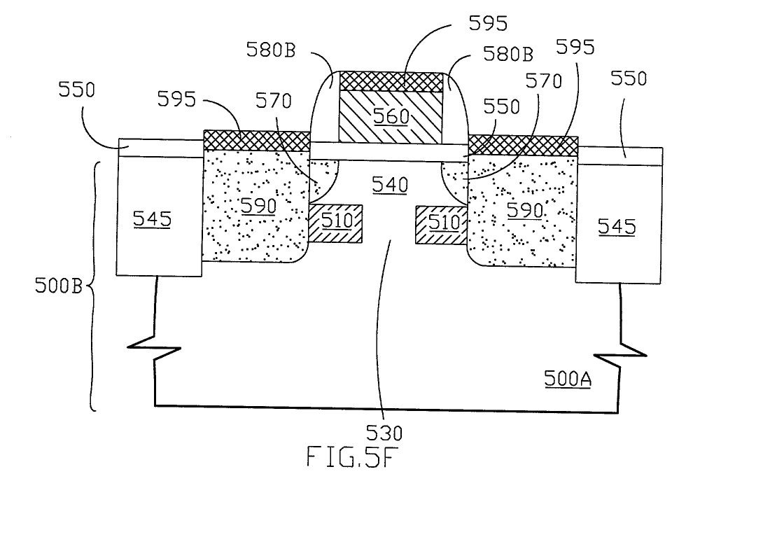

As illustrated in FIG. 5A, in the third embodiment of the present invention, first of all, a first silicon substrate 500A is provided. Then depositing a oxide layer 510 and forming on the first silicon substrate 500A to protect the junctions from leakage. Next, a photoresister layer 520 is formed and defined on the oxide layer 510. The oxide layer 510 is then etched by the photoresister layer 520 as an etching mask to expose a partial surface of the first silicon substrate 500A as an opening 530. After the photoresister layer 520 is removed, a silicon layer 540 is formed over the oxide layer 510 to fill the opening 530 by way of using the epitaxial process. A second silicon substrate 500B combines the silicon layer 540 with the first silicon substrate 500A, as shown in FIG. 5B.

As illustrated in FIG. 5C, in this embodiment, the shallow trench isolation (STI) regions 545 is defined in the second silicon substrate 500B to be as the isolating devices. Then forming a gate oxide layer 550 and a poly gate 560 on the second silicon substrate 500B. Next, a first ion-implantion is performed to form a lightly doped drain region (LDD) region 570 in the silicon layer 540 of the second silicon substrate 500B over the oxide layer 510. A spacer layer 580A is conformed along the surfaces of the poly gate 560 and the gate oxide layer 550. Afterward, the spacer layer 580A is etched by way of using an isotropic dry etching process to form a spacer 580B beside each sidewall of the poly gate 560. proceeding to etch sequentially through the gate oxide layer 550, the silicon layer 540, and the oxide layer 510 with the poly gate 560 having the spacer 580B as an etching mask until exposing the partial surfaces of the first silicon substrate 500A, so as to form the etched regions 585 on the first silicon substrate 500A, as shown in FIG. 5D.

As illustrated in FIG. 5E, in this embodiment, the etched regions 585 are filled with the silicon by a selective epitaxy process to grow the silicon on the first silicon substrate 500A and form a third silicon substrate 500C that combines the etched regions 585 with the second silicon substrate 500B. Subsequently, the source/drain regions 590 are formed respectively in the etched regions 585 by way of using the second ion-implanting process. Finally, performing a conventional salicide process to form the salicide layers 595 on the poly gate 560 and source/drain regions 590, as shown in FIG. 5F.

In these embodiments of the present invention, as discussed above, this invention can avoid causing junction leakage by forming the junction protecting layer, so as to substitute for pocket dopant region and avoid defect of pocket dopant, which is easy to diffuse. Hence, the present invention is appropriate for deep sub-micron technology to provide the semiconductor devices. Furthermore, the present invention can form a source/drain region deep than conventional process by means of the junction protecting layer. Moreover, the junction protecting layer not only could reduce side effects of above, but also eliminate short channel effect. Accordingly, this invention can provide a metal-oxide-semiconductor device which has a performance is better than the conventional one, so as to increase yield and quality of the process and, hence, decrease cost. In other words, the present invention can correspond to economic effect.

Of course, it is possible to apply the present invention to the process for forming the junction, and also it is possible to the present invention to any one metal-oxide-semiconductor devices in the semiconductor devices. Also, this invention can be applied to use junction protected layer concerning the metal-oxide-semiconductor process used for avoiding the junction leakage have not been developed at present. Method of the present invention is the best metal-oxide-semiconductor compatible process for deep sub-micro process.

Obviously, many modifications and variations of the present invention are possible in light of the above teachings. It is therefore to be understood that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for forming an ion-implanting region, said method comprising:
providing a first substrate;
forming a junction protecting layer on said first substrate;
defining a photoresister layer on said junction protecting layer;
etching said junction protecting layer by said photoresister layer as an etching mask to expose a partial surface of said first substrate as an opening;
removing said photoresister layer;
forming a second substrate over said junction protecting layer to fill said opening;
forming an ion-mask on said second substrate; and
forming an ion-implanting region in said second substrate above said junction protecting layer by way of using said ion-mask.

2. The method according to claim 1, wherein said first substrate comprises a silicon material.

3. The method according to claim 1, wherein said junction protecting layer comprises an oxide layer.

4. The method according to claim 1, wherein the method for forming said junction protecting layer comprises a deposition process.

5. The method according to claim 1, wherein said second substrate comprises a silicon material.

6. The method according to claim 1, wherein the width of said opening is less than the width of said ion-mask.

7. The method according to claim 1, wherein the thickness of said ion-implanting region is about equal to the thickness of said second substrate.

8. The method according to claim 1, wherein the thickness of said ion-implanting region is about less then the thickness of said second substrate.

9. A method for forming an metal-oxide-semiconductor device, said method comprising:
providing a first substrate;
forming a protecting layer on said first substrate;
defining a photoresister layer on said protecting layer;
etching said protecting layer by said photoresister layer as an etching mask to expose a partial surface of said first substrate as an opening;
removing said photoresister layer;
overlaying a semiconductor layer on said protecting layer to fill said opening and form a second substrate;
forming a gate on said semiconductor layer of said second substrate;
forming a plurality of first ion-implanting regions in said semiconductor layer above said protecting layer;
conforming an insulator layer along the surfaces of said gate and said semiconductor layer of said second substrate;
etching said insulator layer by way of performing an etching process to form a spacer beside each sidewall of said gate
performing said etching process by way of using said gate having said spacer as an etching mask to remove a portion of said protecting layer and said second substrate;
forming a plurality of predetermined implanting regions on said first substrate; and
forming a plurality of second ion-implanting regions in said plurality of predetermined implanting regions, so as to form said metal-oxide-semiconductor device.

10. The method according to claim 9, wherein said first substrate comprises a silicon material.

11. The method according to claim 9, wherein said protecting layer comprises an oxide layer.

12. The method according to claim 9, wherein the method for forming said protecting layer comprises a deposition process.

13. The method according to claim 9, wherein said semiconductor layer comprises a silicon material.

14. The method according to claim 9, wherein the width of said opening is less than the width of said gate.

15. The method according to claim 9, wherein the thickness of said plurality of first ion-implanting regions are about equal to the thickness of said semiconductor layer.

16. The method according to claim 9, wherein the thickness of said plurality of first ion-implanting regions are about less then the thickness of said semiconductor layer.

17. The method according to claim 9, wherein said etching process comprises an isotropic etching process.

18. The method according to claim 9, wherein said etching process comprises a dry etching process.

19. The method according to claim 9, wherein the method of said etching process is to sequentially etch through said semiconductor layer and said protecting layer until exposing the partial surfaces of said first substrate.

20. The method according to claim 9, wherein the method for forming said plurality of predetermined implanting regions comprises a filling process with a semiconductor material.

21. The method according to claim 19, wherein the semiconductor material comprises a silicon material.

22. The method according to claim 9, wherein the thickness of said plurality of second ion-implanting regions are about equal to the thickness of said plurality predetermined implanting regions.

23. The method according to claim 9, wherein the thickness of said plurality of second ion-implanting regions are about more then the thickness of said plurality predetermined implanting regions.

24. A method for forming an metal-oxide-semiconductor device, said method comprising:
providing a first silicon substrate;
depositing an oxide layer on said first silicon substrate;
defining a photoresister layer on said oxide layer;
etching said oxide layer by said photoresister layer as an etching mask to expose a partial surface of said first silicon substrate as an opening;
removing said photoresister layer;
forming a second silicon substrate over said oxide layer to fill said opening;
forming a shallow trench isolation regions in said second silicon substrate and said first silicon substrate;
forming a gate oxide layer on said second silicon substrate;
forming a poly gate on said gate oxide layer;
forming a lightly doped drain region above said oxide layer in said second silicon substrate;
conforming a nitride layer along the surfaces of said poly gate and said second silicon substrate;
etching said nitride layer by way of using an isotropic dry etching process to form a spacer beside each sidewall of said poly gate;
proceeding to etch sequentially through said gate oxide layer, said second silicon substrate, and said oxide layer until exposing the partial surfaces of said first silicon substrate with said poly gate having said spacer as an etching mask, so as to remove a portion of said gate oxide layer, said second silicon substrate, and said oxide layer;
forming a predetermined implanting region on said first substrate;
forming a source/drain region in said predetermined implanting regions; and
forming a plurality of salicide layers that are located on said poly gate and said source/drain region, respectively, to form said metal-oxide-semiconductor device.

25. The method according to claim 24, wherein the thickness of said oxide layer is about between 500 Å to 800 Å.

26. The method according to claim 24, wherein the method for forming said second silicon substrate comprises an epitaxy process.

27. The method according to claim 24, wherein the thickness of said second silicon substrate is about between 100 Å to 200 Å.

28. The method according to claim 24, wherein the width of said poly gate is more than the width of said opening.

29. The method according to claim 24, wherein the method for forming said predetermined implanting regions comprises a selective epitaxy process.

30. The method according to claim 29, wherein the material of said selective epitaxy process comprises a silicon material.
